(19) United States
(12) Patent Application Publication
(10) Pub. No.: US 2015/0222032 A1
(43) Pub. Date: Aug. 6, 2015

(54) PRINTED CIRCUIT BOARD AND DISPLAY DEVICE INCLUDING THE SAME

(71) Applicant: SAMSUNG DISPLAY CO., LTD., YONGIN-CITY (KR)

(72) Inventors: Nam Hee GOO, Suwon-si (KR); Ki Hyuk KIM, Seoul (KR); Jung Soo YOUN, Seoul (KR); Seuk Whan LEE, Suwon-si (KR)

(21) Appl. No.: 14/320,353

(22) Filed: Jun. 30, 2014

(30) Foreign Application Priority Data
Feb. 5, 2014 (KR) 10-2014-0013169

(51) Int. Cl. H01R 12/62; H05K 7/06; H01R 12/52

(52) U.S. Cl. CPC H01R 12/62; H01R 12/52; H05K 7/06

(57) ABSTRACT

A printed circuit board includes a base member including a major surface; a first region and a second region adjacent to the first region when viewed in a direction perpendicular to the major surface; a first conductive pattern layer formed over the major surface and comprising a plurality of conductive features positioned in the first region; and a connector placed over the major surface and comprising a portion located in the second region. The first conductive pattern layer does not comprise a portion formed in the second region and overlapping the connector when viewed in the direction.

### CROSS-REFERENCE TO RELATED APPLICATIONS

This application is based on and claims priority from Korean Patent Application No. 10-2014-0013169, filed on Feb. 5, 2014 in the Korean Intellectual Property Office, to the disclosure of which is incorporated herein in its entirety by reference.

### BACKGROUND

1. Field

The present disclosure relates to a printed circuit board and a display device including the same.

2. Description of the Prior Art

A display device is a device that displays data. The display device may be a liquid crystal display, an electrophoretic display, an organic light emitting display, an inorganic electroluminescent (EL) display, a field emission display, a surface-conduction electron-emitter display, a plasma display, or a cathode ray display.

In general, the display device includes at least one printed circuit board to mount an integrated circuit thereon and to transfer signals. The printed circuit board transfers the signals through connectors connected to the printed circuit board.

### SUMMARY

However, the printed circuit board and the connectors are not integrally formed, but are separately formed to be combined with each other. Accordingly, impedance matching may not be performed in a connection portion between the printed circuit board and the connectors, and this may cause signal integrity (SI) characteristics of the display device to deteriorate.

In particular, with the increase of a transfer speed such as in a multi-Gbps (Giga bit per sec) ultra-high speed interface, the influence that is caused by impedance mismatch in the connection portion between the printed circuit board and the connectors may be increased.

Accordingly, one aspect of the present invention provides a printed circuit board that can improve signal integrity characteristics through structural optimization of a connector connection portion.

Another aspect of the present invention provides a display device including a printed circuit board that can improve signal integrity characteristics through structural optimization of a connector connection portion.

Additional advantages, subjects, and features of the invention will be set forth in part in the description which follows and in part will become apparent to those having ordinary skill in the art upon examination of the following or may be learned from practice of the invention.

One aspect of the invention provides a printed circuit board comprising: a base member including a major surface; a first region and a second region adjacent to the first region when viewed in a direction perpendicular to the major surface; a first conductive pattern layer formed over the major surface and comprising a plurality of conductive features positioned in the first region; and a connector placed over the major surface and comprising a portion located in the second region, wherein the first conductive pattern layer does not comprise a portion formed in the second region such that the first conductive pattern layer does not overlap the connector in the second region when viewed in the direction.

In the foregoing printed circuit board (PCB), the PCB may further comprise a second conductive pattern layer embedded in the base member or formed over another surface of the base member, wherein the second conductive pattern layer does not comprise a portion formed in the second region. The second region may comprise at least a part of an edge of the base member. The connector does not overlap the second conductive pattern layer when viewed in the direction. Two or more of the plurality of conductive features are connected to the connector, and a minimum width of each of the two or more of the plurality of conductive features that are connected to the connector may be smaller than a minimum width of each of the other conductive features that are not connected to the connector. The minimum width of each of the plurality of conductive features that are connected to the connector may be about 0.1 mm.

Still in the foregoing PCB, the base member may comprise an insulator that is interposed between the first and second conductive pattern layers. The printed circuit board may further comprise a third conductive pattern layer embedded in the base member or formed over the other surface of the base member, wherein the second conductive pattern layer is located between the first and third conductive pattern layers, wherein the base member further comprises at least one insulator between the second and third conductive pattern layer, and wherein the third conductive pattern layer does not comprise a portion formed in the second region. The printed circuit board may further comprise at least one additional conductive pattern layer embedded in the base member or formed over the other surface of the base member, wherein the at least one additional conductive pattern layer does not overlap the connector when viewed in the direction.

Another aspect of the invention provides a printed circuit board comprising: a base member including a major surface; a first region and a second region that is adjacent to the first region when viewed in a direction perpendicular to a major surface of the base member; a plurality of conductive features formed over the major surface and positioned in the first region; a plurality of conductive pattern layers, each of which is embedded in the base member or formed over another surface of the base member; and a connector placed over the major surface and comprising a portion located in the second region, wherein each of the plurality of conductive pattern layers comprises a portion in the first region, wherein at least one of the plurality of conductive pattern layers does not comprise a portion formed in the second region.

In the foregoing printed circuit board, wherein the connector may comprise at least one conductive terminal connected to at least one of the plurality of conductive features, and extending to the second region. Each of the plurality of conductive pattern layers does not overlap the connector when viewed in the direction. The base member may comprise a plurality of insulator layers that are stacked, and the plurality of conductive pattern layers and the plurality of insulator layers are alternately stacked with each other.

A further aspect of the invention provides a display device comprising: a display panel configured to display an image; a first printed circuit board connected to the display panel, comprising: a base member including a major surface, a first region and a second region adjacent to the first region when viewed in a direction perpendicular to the major surface, and a conductive pattern layer formed over the major surface and comprising a plurality of conductive features positioned in the first region; and a connector attached to the printed circuit board, placed over the major surface and comprising a portion located over the second region, wherein the first conductive pattern layer does not comprise a portion formed in the second region such that the first conductive pattern layer does not overlap the connector in the second region when viewed in the direction.

In the foregoing device, the display device may further comprise a flexible cable comprising an end portion which is connected the connector and does not overlap the first conductive pattern layer when viewed in the direction. The display device may further comprise at least one additional conductive pattern layer embedded in the base member or formed over the other surface of the first base member, wherein the at least one additional conductive pattern layer does not comprise a portion formed in the second region and overlapping either the connector or the flexible cable when viewed in the direction. The display device may further comprise a second printed circuit board connected to the first printed circuit board using the flexible cable.

Still in the foregoing display device, the device may further comprise an additional conductive pattern layer embedded in the base member or formed over the other surface of the first base member, wherein the additional conductive pattern layer does not overlap either the connector or the flexible cable when viewed in the direction. Two or more of the plurality of second conductive features may be connected to the connector, and a minimum width of each of the two or more of the plurality of second conductive features that are connected to the second connector is smaller than a minimum width of each of the other conductive features that are not connected to the connector. The display device may further comprise two or more additional conductive pattern layers embedded in the base member or formed over the other surface of the first base member, wherein a first one of the two or more additional conductive pattern layers does not comprise a portion overlapping the end portion of the flexible cable when viewed in the direction, wherein a second one of the two or more additional conductive pattern layers overlaps the end portion of the flexible cable when viewed in the direction.

In one aspect of the present invention, A printed circuit board may comprise a base member including a first region where at least one conductive layer is positioned and a second region that is adjacent to the first region, and a plurality of conductive features positioned on the at least one conductive layer.

The at least one conductive layer is not formed in the second region.

The second region may be at least a part of an edge portion of the base member.

The second region may be a region where at least a part of a connector that is connected to at least one of the plurality of conductive features is arranged.

Parts of the plurality of conductive features may be connected to the connector, and a minimum width of each of the plurality of conductive features that are connected to the connector may be smaller than a minimum width of each of the plurality of conductive features that are not connected to the connector.

The minimum width of each of the plurality of conductive features that are connected to the connector may be 0.1 mm.

The base member may further comprise an insulating layer that is interposed between the plurality of conductive features and the at least one conductive layer.

The base member may further comprise at least one insulating layer, and the at least one insulating layer may be positioned in both the first region and the second region.

A plurality of conductive layers and insulating layers may be provided, and the plurality of conductive layers and insulating layers may be alternately stacked with each other.

In another aspect of the present invention, a printed circuit board may comprise a base member including a first region and a second region that is adjacent to the first region, and a plurality of conductive features positioned in the first region of the base member, wherein the base member includes a plurality of conductive layers that are successively stacked, all the plurality of conductive layers exist in the first region, and at least one of the plurality of conductive layers does not exist in the second region.

The second region may be a region where a connector that is connected to at least one of the plurality of conductive features is arranged.

At least one of the plurality of conductive layers that does not exist in the second region may be adjacent to the connector.

The base member may further comprise a plurality of insulating layers that are successively stacked, and the plurality of conductive layers and the plurality of insulating layers may be alternately stacked with each other.

In another aspect of the present invention, a display device may comprise a display panel configured to display an image, and a first printed circuit board connected to the display panel, wherein the first printed circuit board includes a first base member including a first region where at least one first conductive layer is positioned and a second region that is adjacent to the first region, and a plurality of first conductive features positioned on the at least one first conductive layer.

The display device may further comprise a first connector positioned on the first printed circuit board and connected to at least one of the plurality of first wiring patterns, wherein at least a part of the first connector may be positioned in the second region of the first base member.

Parts of the plurality of first conductive features may be connected to the first connector, and a minimum width of each of the plurality of first conductive features that are connected to the first connector may be smaller than a minimum width of each of the plurality of first conductive features that are not connected to the first connector.

The display device may further comprise a second printed circuit board connected to the first printed circuit board, wherein the second printed circuit board may include a second base member including a first region where at least one second conductive layer is positioned and a second region that is adjacent to the first region, and a plurality of second conductive features positioned on the at least one second conductive layer.

The display device may further comprise a second connector positioned on the second printed circuit board and connected to at least one of the plurality of second wiring patterns, wherein at least a part of the second connector may be positioned in the second region of the second base member.

Parts of the plurality of second conductive features may be connected to the second connector, and a minimum width of each of the plurality of second conductive features that are connected to the second connector may be smaller than a minimum width of each of the plurality of second conductive features that are not connected to the second connector.

The display device may further comprise a flexible cable configured to connect the first connector and the second connector to each other.

According to the embodiments of the present invention, at least the following effects can be achieved.

It becomes possible to provide a display device having improved signal integrity characteristics.

The effects according to embodiments of the present invention are not limited to the contents as exemplified above, but further various effects are included in the description.

### BRIEF DESCRIPTION OF THE DRAWINGS

The above and other features and advantages of the present invention will be more apparent from the following detailed description taken in conjunction with the accompanying drawings, in which:

FIG. 1 is a plan view of a display device according to an embodiment of the present invention;

FIG. 2 is an enlarged perspective view of a portion II of FIG. 1;

FIG. 3 is an enlarged plan view of a portion II of FIG. 1;

FIG. 4 is an enlarged plan view of a portion IV of FIG. 3;

FIG. 5 is a cross-sectional view taken along line V-V′ of FIG. 3;

FIG. 6 is a cross-sectional view taken along line VI-VI′ of FIG. 3;

FIG. 7 is a graph illustrating the results of measuring time domain reflectometry of the display device of FIG. 1;

FIG. 8 is an enlarged graph of a portion VIII of FIG. 7;

FIG. 9 is a graph illustrating the results of analyzing an S parameter of the display device of FIG. 1;

FIG. 10 is an enlarged graph illustrating a portion X of FIG. 9;

FIG. 11 is a perspective view of a first printed circuit board, a first connector, and a flexible cable of a display device according to another embodiment of the present invention;

FIG. 12 is a plan view of the first printed circuit board, the first connector, and the flexible cable of FIG. 11;

FIG. 13 is a perspective view of a first printed circuit board, a first connector, and a flexible cable of a display device according to still another embodiment of the present invention;

FIG. 14 is a plan view of the first printed circuit board, the first connector, and the flexible cable of FIG. 11;

FIG. 15 is a cross-sectional view taken along line XV-XV′ of FIG. 14; and

FIGS. 16 to 19 are cross-sectional views of first printed circuit boards of display devices according to other embodiments of the present invention.

### DETAILED DESCRIPTION OF EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Thus, in some embodiments, well-known structures and devices are not shown in order not to obscure the description of the invention with unnecessary detail. Like numbers refer to like elements throughout. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Hereinafter, embodiments of the present invention will be described with reference to the accompanying drawings.

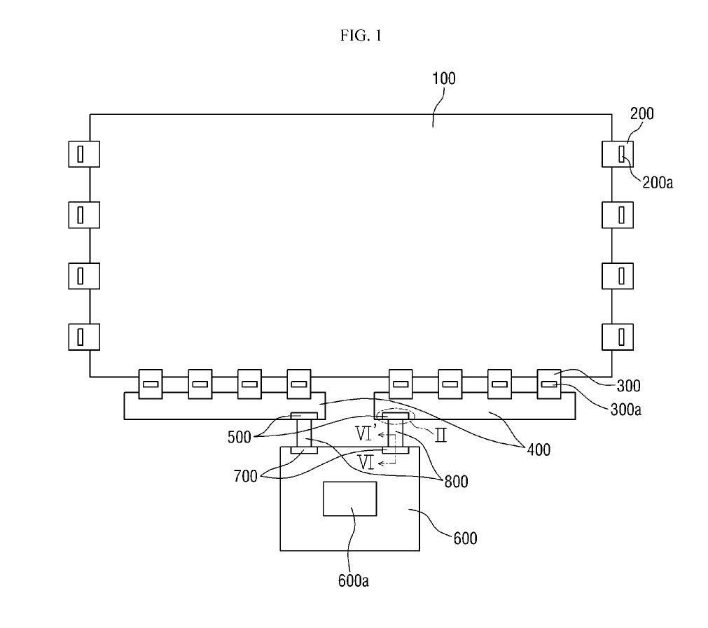

FIG. 1 is a plan view of a display device according to an embodiment of the present invention. Referring to FIG. 1, a display device according to an embodiment of the present invention may include a display panel 100, a gate tape carrier package 200, a gate integrated circuit 200a, a data tape carrier package 300, a data integrated circuit 300a, a first printed circuit board 400, a first connector 500, a second printed circuit board 600, a timing controller 600a, a second connector 700, and a flexible cable 800.

The display panel 100 is a panel that displays data. The display panel 100 may be a liquid crystal display (LCD) panel, an electrophoretic display panel, an organic light emitting display (OLED) panel, a light emitting diode (LED) panel, an inorganic electroluminescent (EL) display panel, a field emission display (FED) panel, a surface-conduction electron-emitter display (SED) panel, a plasma display panel (PDP), or a cathode ray tube (CRT) display panel. Hereinafter, as a display device according to an embodiment of the present invention, a liquid crystal display is exemplified, and as a display panel 100, an LCD panel is exemplified. However, the display device and the display panel 100 according to embodiments of the present invention are not limited thereto, and various types of display devices and display panels may be used.

Although not illustrated in the drawing, the display panel 100 may include a display region where an image is displayed and a non-display region where an image is not displayed. In an exemplary embodiment, the display region may be surrounded by the non-display region. For example, the display region may be a center region of the display panel 100, and the non-display region may be an edge region of the display panel 100.

Further, although not illustrated in the drawing, the display panel 100 may include a first substrate, a second substrate that faces the first substrate, and a liquid crystal layer interposed between the first substrate and the second substrate. The first substrate and the second substrate may be in a cuboidal shape. However, the shape of the first substrate and the second substrate is not limited thereto, but the first substrate and the second substrate may be manufactured in various shapes. Further, between the first substrate and the second substrate, a sealing member, such as a sealant, may be arranged along the edge portions of the first substrate and the second substrate to attach and seal the first substrate and the second substrate.

The gate tape carrier package (TCP) 200 may be connected to at least one side of the display panel 100. In an exemplary embodiment, the gate tape carrier package 200 may be formed in the non-display region of the display panel 100. Further, the gate tape carrier package 200 may be positioned on two short sides of the display panel 100, but is not limited thereto. The gate tape carrier package 200 may be positioned on one short side or long side of the display panel 100.

The gate tape carrier package 200 may include a flexible film. In an exemplary embodiment, such a flexible film may be made of a plastic material.

A plurality of gate tape carrier packages 200 may be provided. The plurality of gate tape carrier package 200 may be arranged to be spaced apart from each other by a predetermined distance. In an exemplary embodiment illustrated in FIG. 1, four gate tape carrier packages 200 may be positioned on one short side, and four gate tape carrier packages 200 may be positioned on the other short side that is opposite to the one short side, but are not limited thereto.

The gate integrated circuit 200a may be mounted on the gate tape carrier package 200. The gate integrated circuit 200a may be connected to a plurality of gate lines (not illustrated) of the display panel 100 via the gate tape carrier package 200. The gate integrate circuit 200a may successively provide a scan signal of a gate high voltage to the plurality of gate lines. Further, the gate integrated circuit 200a may supply a gate low voltage to the plurality of gate lines in the remaining period except for a period when the gate high voltage is supplied.

The data tape carrier package 300 may be connected to at least one side of the display panel 100. In an exemplary embodiment, the data tape carrier package 300 may be formed in the non-display region of the display panel 100. Further, the data tape carrier package 300 may be positioned on one long side of the display panel 100, but is not limited thereto. The data tape carrier package 300 may be positioned on two long sides or short sides of the display panel 100.

The data tape carrier package 300 may include a flexible film. In an exemplary embodiment, such a flexible film may be made of a plastic material.

A plurality of data tape carrier packages 300 may be provided. The plurality of data tape carrier package 300 may be arranged to be spaced apart from each other by a predetermined distance. In an exemplary embodiment illustrated in FIG. 1, eight data tape carrier packages 300 may be positioned on one long side, but are not limited thereto.

The data integrated circuit 300a may be mounted on the data tape carrier package 300. The data integrated circuit 300a may be connected to a plurality of data lines (not illustrated) of the display panel 100 via the data tape carrier package 300. The data integrate circuit 300a may convert pixel data into an analog pixel signal and supply the analog pixel signal to the plurality of data lines.

The first printed circuit board (PCB) 400 may be connected to the data tape carrier package 300. In embodiments, one end of the data tape carrier package 300 may be connected to the display panel 100, and the other end of the data tape carrier package 300 that faces the one side may be connected to the first printed circuit board 400. The first printed circuit board 400 may be a source printed circuit board. The first printed circuit board 400 may supply a control signal that is output from the timing controller 600a mounted on the second printed circuit board 600 to be described later to the data integrated circuit 300a.

A plurality of printed circuit boards 400 may be provided. In an exemplary embodiment, two first printed circuit boards 400 may be arranged along the long side of the display panel 100, but are not limited thereto. In an exemplary embodiment illustrated in FIG. 1, the plurality of first printed circuit boards 400 may be connected to four data tape carrier packages 300, respectively, but are not limited thereto.

The first connector 500 may be connected to the first printed circuit board 400. In an exemplary embodiment, the first connector 500 may be positioned on the other side of the first printed circuit board 400 that faces one side of the first printed circuit board 400 to which the gate tape carrier package 200 is connected. The first connector 500 may transfer a control signal that is output from the timing controller 600a mounted on the second printed circuit board 600 to be described later to the first printed circuit board 400.

A plurality of first connectors 500 may be provided. In an exemplary embodiment, the plurality of first connectors 500 may be positioned on the plurality of first printed circuit boards 400, respectively. In embodiments, the first connectors 500 and the first printed circuit boards 400 may have one-to-one correspondence relationship.

The structure of a connection portion between the first printed circuit board 400 and the first connector 500 will be described in detail later.

The second printed circuit board 600 may be connected to the first printed circuit board 400. In embodiments, the second printed circuit board 600 may be connected to the first printed circuit board 400 through the flexible cable 800 to be described later. The second printed circuit board 600 may be a control printed circuit board. The second printed circuit board 600 may transfer a control signal that is output from the timing controller 600a to be described later to the first connector 500.

One second printed circuit board 600 may be provided. In an exemplary embodiment, one second printed circuit board 600 may be connected to two first printed circuit boards 400, but is not limited thereto.

The timing controller 600a may be mounted on the second printed circuit board 600. The timing controller 600a may output various kinds of control signals that are transferred to the display panel 100 to match the timing thereof. The control signals generated by the timing controller 600a may be transferred to the data integrated circuit 300a via the second printed circuit board 600, the second connector 700, the flexible cable 800, the first connector 500, the first printed circuit board 400, and the data tape carrier package 300.

The second connector 700 may be connected to the second printed circuit board 600. In an exemplary embodiment, the second connector 700 may be positioned on one side of the second printed circuit board 600 that faces the first printed circuit board 400. The second connector 700 may transfer the control signals from the timing controller 600a to be described later to the first connector 500.

A plurality of second connectors 700 may be provided. In an exemplary embodiment, the plurality of second connectors 700 may be positioned on one second printed circuit boards 600. The plurality of second connectors 700 may correspond to the plurality of first connectors 500, respectively. That is, the first connectors 500 and the second connectors 700 may have one-to-one correspondence relationship.

The structure of a connection portion between the second printed circuit board 600 and the second connector 700 will be described in detail later.

The flexible cable 800 may connect the first connector 500 and the second connector 700 to each other. In an exemplary embodiment, the flexible cable 800 may be a flat flex cable (FFC). The flexible cable 800 may have a structure in which insulating plastic surrounds a metal thin film. The flexible cable 800 may serve to transfer the control signal generated by the timing controller 600a from the second connector 700 to the first connector 500.

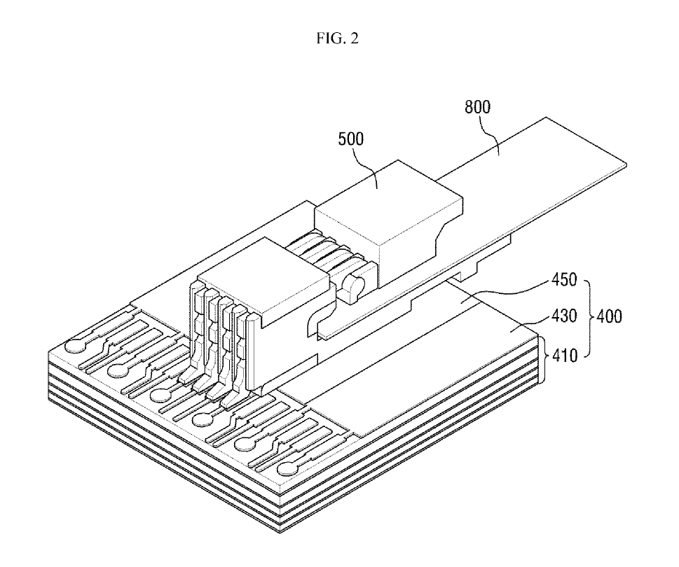

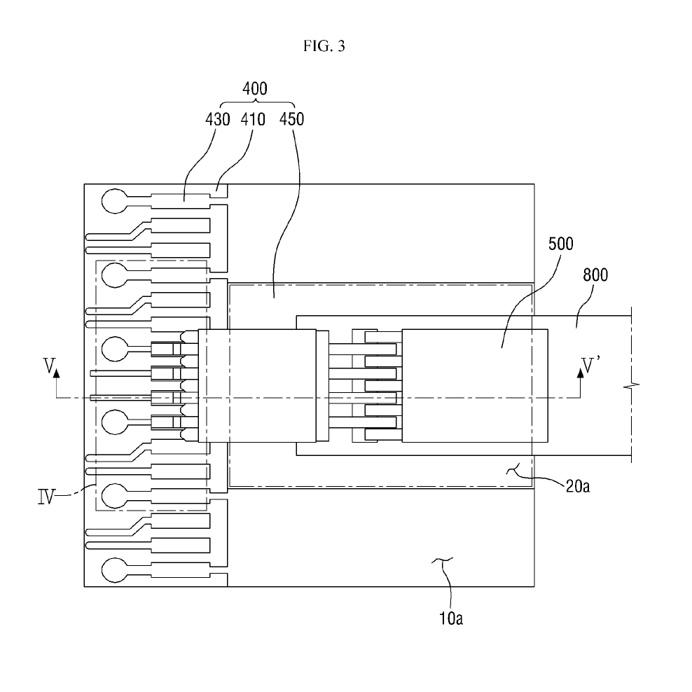

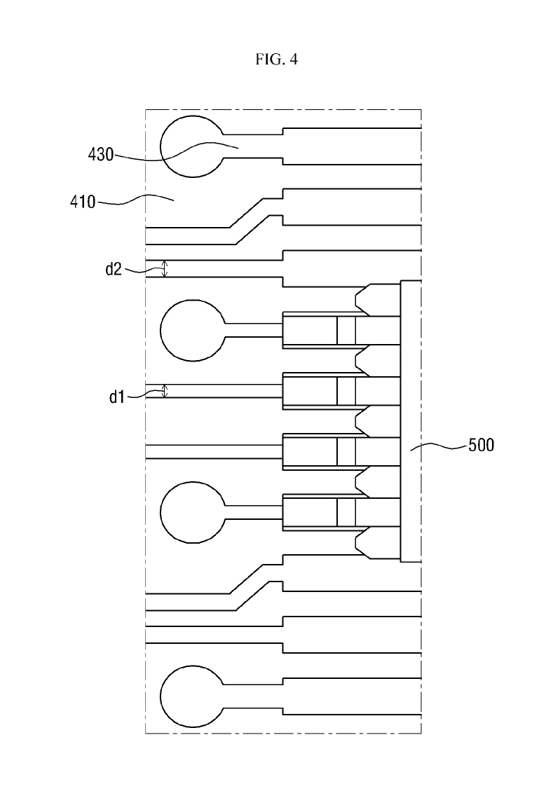

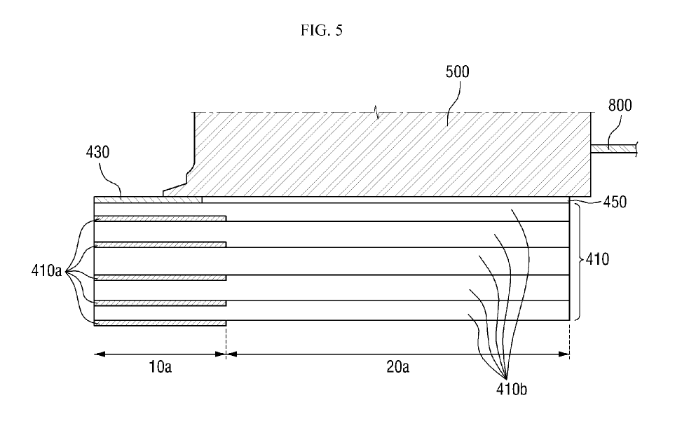

Hereinafter, the structure of the connection portion between the first printed circuit board 400 and the first connector 500 in accordance with embodiments will be described in detail with reference to FIGS. 2 to 5. FIG. 2 is an enlarged perspective view of a portion II of FIG. 1, and FIG. 3 is an enlarged plan view of a portion II of FIG. 1. FIG. 4 is an enlarged plan view of a portion IV of FIG. 3, and FIG. 5 is a cross-sectional view taken along line V-V′ of FIG. 3.

Referring to FIGS. 2 to 5, the first printed circuit board 400 may include a first base member 410, a plurality of first conductive features 430, and a first adhesive layer 450. In embodiments, the conductive features may include conductive tracks, conductive wires, conductive pads and other features formed on an insulator substrate for forming a printed circuit board. Such conductive features may be provided by forming a conductive metal layer, for example, copper layer, on the insulation substrate and patterning the conductive metal layer to form a conductive pattern layer with the conductive features, but not limited thereto.

The first base member 410 may be a base that forms the first printed circuit board 400. The first base member 410 may include at least one first conductive layer 410a and at least one first insulating layer 410b.

The first conductive layer 410a may be made of a conductive material. In an exemplary embodiment, the first conductive layer 410a may be a copper foil layer, but is not limited thereto. The first conductive layer 410a may be made of various conductive materials that can transfer an electrical signal. In embodiments, the first conductive layer 410a may include a ground of a circuit.

The first insulating layer 410b may be made of an insulating material. In an exemplary embodiment, the first insulating layer 410b may be made of a resin that includes polyimide (PI), but is not limited thereto. The first insulating layer 410b may be made of various insulating materials.

The first base member 410 may include a plurality of first conductive layers 410a and a plurality of first insulating layers 410b. The plurality of first conductive layers 410a and the plurality of first insulating layers 410b may be alternately stacked. In an exemplary embodiment illustrated in FIGS. 2 to 5, five first conductive layers 410a and five insulating layers 410b may be stacked, but are not limited thereto. That is, the first base member 410 may have a multilayer structure.

Although not illustrated in the drawing, at least one of the plurality of first insulating layers 410b may include at least one via hole that connects the plurality of first conductive layers 410a and the plurality of first conductive features 430 to each other.

In embodiments, the printed circuit board may include a first region 10a and a second region 20a when viewed in a viewing direction perpendicular to a major surface of t0 the base member. The second region 20a is next to the first region 10a.

The first region 10a may be a region where the first conductive layer 410a is positioned. Further, the first region 10a may be a region where the plurality of first conductive features 430 are positioned. Further, the first region 10a may be a center region of the first base member 410.

The second region 20a may be adjacent to the first region 10a. The second region 20a may be a region where the first conductive layer 410a is not positioned. Further, the second region 20a may be a region where the plurality of first conductive features 430 are not positioned. Further, the second region 20a may be a part of an edge region of the first base member 410. Further, the second region 20a may be a region where a part of the first connector 500 is arranged. In an exemplary embodiment, the second region 20a may be a region that corresponds to a main body of the first connector 500. In embodiments, the first connector 500 includes a plurality of conductive terminals each of which is attached to one of the corresponding conductive features 430 in the first region.

As described above, the first conductive layer 410a may be positioned only in the first region 10a, and the first insulating layer 410b may be positioned in both the first region 10a and the second region 20a.

The plurality of first conductive features 430 may be positioned on the first base member 410. Specifically, the plurality of first conductive features 430 may be positioned on the first conductive layer 410a. Further, the plurality of first wiring pattern 430 may be positioned in the first region 10a. Further, the plurality of first conductive features 430 may not be positioned in the second region 20a. Further, the plurality of first conductive features 430 may be directly positioned on the first insulating layer 410b. That is, the first insulating layer 410b may be interposed between the plurality of first conductive features 430 and the first conductive layer 410a. Control signals that are transferred from the timing controller 600a may be applied to the plurality of conductive features 430.

The plurality of first conductive features 430 may be made of a conductive material. In an exemplary embodiment, the plurality of first conductive features 430 may be made of the same material as the first conductive layer 410a. The plurality of first conductive features 430 may have impedance of about 100 ohms.

Parts of the plurality of first conductive features 430 may be connected to the first connector 500. In an exemplary embodiment illustrated in FIGS. 2 to 4, four first conductive features 430 are connected to the first connector 500, but are not limited thereto.

The minimum width d1 of each of the plurality of first conductive features 430 that are connected to the first connector 500 may be smaller than the minimum width d2 of each of the plurality of first conductive features 430 that are not connected to the first connector 500. In an exemplary embodiment, referring to FIG. 4, the minimum width d1 of each of the plurality of first conductive features 430 that are connected to the first connector 500 may be about 0.8 mm to about 1.2 mm. Preferably, the minimum width d1 of each of the plurality of first conductive features 430 that are connected to the first connector 500 may be about 1 mm. The minimum width d1 of each of the plurality of first conductive features 430 that are connected to the first connector 500 may be determined by the amount of increase of necessary inductance and the tolerance in a process of manufacturing the first printed circuit board 400 to be described later. Further, the minimum width d2 of each of the plurality of first conductive features 430 that are not connected to the first connector 500 may be about 1.2 mm to about 1.6 mm. The minimum width d2 of each of the plurality of first conductive features 430 that are not connected to the first connector 500 may be preferably about 1.4 mm.

The first adhesive layer 450 may be positioned on the first base member 410. Specifically, the first adhesive layer 450 may be positioned in the second region 20a. Further, the first adhesive layer 450 may be positioned on the same plane as the plurality of first conductive features 430. Further, the first adhesive layer 450 may be interposed between the first connector 500 and the first base member 410. The first adhesive layer 450 may serve to fix the first connector 500 to the first base member 410. The first adhesive layer 450 may be made of an adhesive resin that is generally used. The first adhesive layer 450 may be omitted according to circumstances.

As described above, the main body of the first connector 500 may be arranged in the second region 20a of the first base member 410, on which the first conductive layer 410a is not positioned, to be electrically connected to parts of the plurality of first conductive features 430.

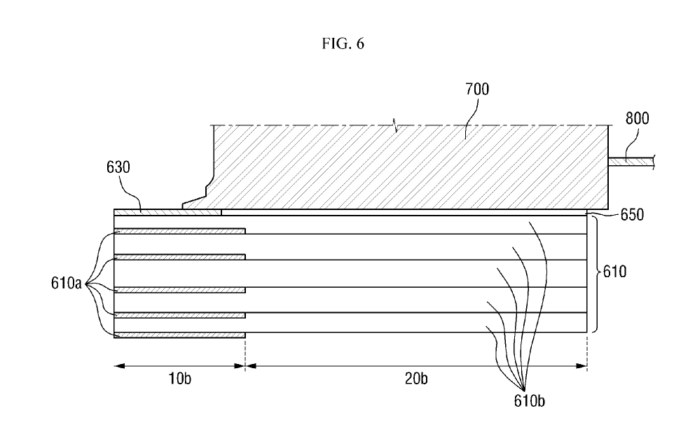

Hereinafter, the structure of the connection portion between the second printed circuit board 600 and the second connector 700 will be described in detail with reference to FIG. 6. FIG. 6 is a cross-sectional view taken along lint VI-VI′ of FIG. 1.

Referring to FIG. 6, a second printed circuit board 600 may include a second base member 610, a plurality of second conductive features 630, and a second adhesive layer 650.

The second base member 610 may include at least one second conductive layer 610a and at least one second insulating layer 610b. Since the second conductive layer 610a and the second insulating layer 610b have substantially the same material and structure as the first conductive layer 410a and the first insulating layer 410b as described above, the detailed description thereof will be omitted.

The second base member 610 may include a first region 10b and a second region 20b. Since the first region 10b and the second region 20b mean substantially the same regions as the first region 10a and the second region 20a as described above, the detailed description thereof will be omitted.

The plurality of second conductive features 630 may be positioned on the second base member 610. Since the plurality of second conductive features 630 have substantially the same material and structure as the plurality of first conductive features 430 as described above, the detailed description thereof will be omitted.

The second adhesive layer 650 may be positioned on the second base member 610. Since the second adhesive layer 650 has substantially the same material and structure as the first adhesive layer 450 as described above, the detailed description thereof will be omitted.

As described above, the connection structure between the first printed circuit board 400 and the first connector 500 may be substantially the same as the connection structure between the second printed circuit board 600 and the second connector 700.

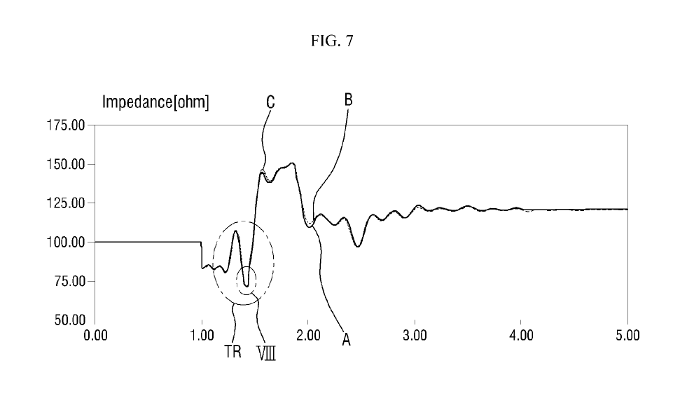

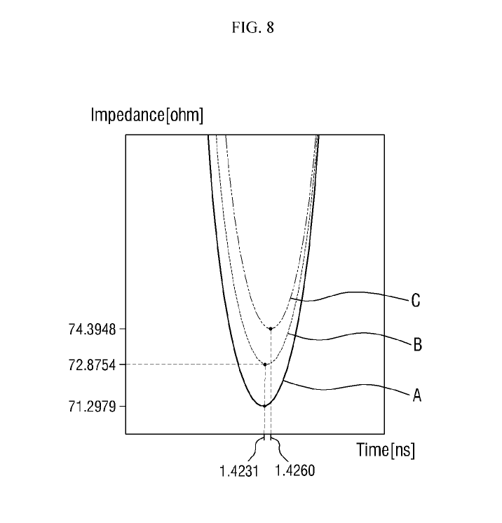

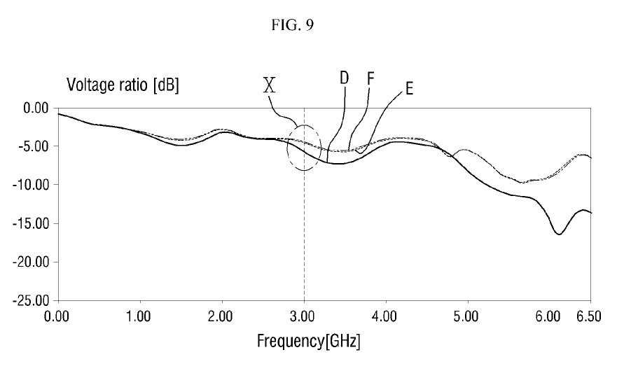

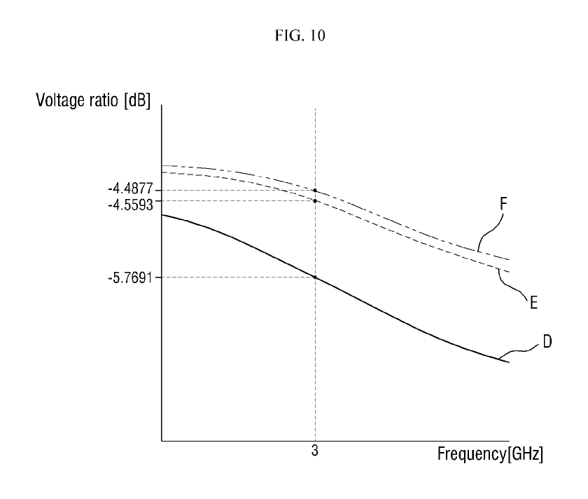

According to an embodiment of the present invention as described above, the signal integrity characteristics of the display device can be improved by the connection structure between the first printed circuit board 400 and the first connector 500 and the connection structure between the second printed circuit board 600 and the second connector 700. This will be described in detail with reference to FIGS. 7 to 10. FIG. 7 is a graph illustrating the results of measuring time domain reflectometry of the display device of FIG. 1, and FIG. 8 is an enlarged graph of a portion VIII of FIG. 7. FIG. 9 is a graph illustrating the results of analyzing an S parameter of the display device of FIG. 1, and FIG. 10 is an enlarged graph illustrating a portion X of FIG. 9.

First, referring to FIGS. 7 and 8, graph A of FIG. 7 is a graph in the case where the first conductive layer 410a and the second conductive layer 610a exist not only in the first regions 10a and 10b but also in the second regions 20a and 20b, and the minimum width of the plurality of first conductive features 430 and the plurality of second conductive features 630 is constantly about 1.4 mm. On the other hand, a transition region TR of FIG. 7 is a region that corresponds to the connection region between the first printed circuit board 400 and the first connector 500 and the connection region between the second printed circuit board 600 and the second connector 700. That is, if the first conductive layer 410a and the second conductive layer 610a exist not only in the first regions 10a and 10b but also in the second regions 20a and 20b, and the minimum width of the plurality of first conductive features 430 and the plurality of second conductive features 630 is constantly about 1.4 mm (graph A), the impedance is excessively lowered in the transition region TR. Referring to FIG. 8, the minimum point of the graph A is about 71.2979 ohms at about 1.4231 ns. Such excessive impedance lowering may deteriorate the signal integrity characteristics.

The excessive impedance lowering may be mainly caused by parasitic capacitance between the first connector 500 and the first conductive layer 410a, parasitic capacitance between the second connector 700 and the second conductive layer 610a, parasitic capacitance between the plurality of first conductive features 430, and parasitic capacitance between the plurality of second conductive features 630. Accordingly, a method for decreasing the parasitic capacitance or increasing the inductance based on an impedance formula, Z₀=root (L/C) (here, Z₀ is the characteristic impedance, L is the inductance, and C is the capacitance), may be considered.

First, the first conductive layer 410a of the lower portion of the main body of the first connector 500 and the second conductive layer 610a of the lower portion of the main body of the second connector 700 may be removed (graph B). Through this, if the first conductive layer 410a of the lower portion of the main body of the first connector 500 and the second conductive layer 610a of the lower portion of the main body of the second connector 700 are removed, the parasitic capacitance between the first connector 500 and the first conductive layer 410a and the parasitic capacitance between the second connector 700 and the second conductive layer 610a can be removed, and thus the impedance in the transition region TR can be prevented from being excessively decreased. Referring to FIG. 8, the minimum point of the graph B is about 72.8754 ohms at about 1.4231 ns. That is, the impedance on the condition of graph B with respect to the condition of graph A is increased by about 1.57 ohms in the transition region TR.

Next, the minimum width of each of the plurality of first conductive features 430 connected to the first connector 500 and the minimum width of each of the plurality of second conductive features 630 connected to the second connector 700 may be decreased (graph C) simultaneously with the removal of the first conductive layer 410a of the lower portion of the main body of the first connector 500 and the second conductive layer 610a of the lower portion of the main body of the second connector 700. As described above, if the minimum width of each of the plurality of first conductive features 430 connected to the first connector 500 and the minimum width of each of the plurality of second conductive features 630 connected to the second connector 700 are decreased, the distance between the plurality of first conductive features 430 connected to the first connector 500 and the distance between the plurality of second conductive features 630 connected to the first connector 500 can be increased, and thus the parasitic capacitance between the plurality of first conductive features 430 and the parasitic capacitance between the plurality of second conductive features 630 can be decreased. Further, if the minimum width of each of the plurality of first conductive features 430 connected to the first connector 500 and the minimum width of each of the plurality of second conductive features 630 connected to the second connector 700 are decreased, the impedance in this portion is increased. Accordingly, the impedance in the transition region TR can be prevented from being excessively decreased. Referring to FIG. 8, the minimum point of the graph C is about 74.3948 ohms at about 1.4260 ns. That is, the impedance on the condition of graph C with respect to the condition of graph B is increased by about 1.52 ohms in the transition region TR.

As a result, the impedance on the condition of graph C with respect to the condition of graph A is improved by about 3.09 ohms in the transition region TR. That is, the display device according to an embodiment of the present invention has superior signal integrity characteristics in the connection portion between the first printed circuit board 400 and the first connector 500 and the connection portion between the second printed circuit board 600 and the second connector 700.

Next, FIGS. 9 and 10 are referred to. FIG. 9 illustrates the results of measuring a forward transfer coefficient (S21) of an S parameter. The conditions of graphs D, E, and F of FIG. 9 correspond to the conditions of graphs A, B, and C of FIG. 7, respectively. Referring to FIG. 10, in the ultra-high speed driving of 6 Gbps (3 GHz), the minimum point of graph D is −5.7691 dB, the minimum point of graph E is −4.5593 dB, and the minimum point of graph F is −4.4877 dB. That is, in the ultra-high speed driving of 3 GHz, the S21 characteristics on the condition of graph F with respect to the condition of graph D are improved by about 1.28 dB. That is, the display device according to an embodiment of the present invention has superior signal integrity characteristics in the connection portion between the first printed circuit board 400 and the first connector 500 and the connection portion between the second printed circuit board 600 and the second connector 700.

On the other hand, although not illustrated in the drawing, as the results of testing the signal integrity characteristics through application of the condition of 6 Gbps in a linear source, the eyeheight on the condition of graph C of FIG. 7 (or the condition of graph F of FIG. 9) with respect to the condition of graph A of FIG. 7 (or the condition of graph D of FIG. 9) is increased from about 317 mV to about 383 mV. That is, the eyeheight on the condition of graph C of FIG. 7 (or the condition of graph F of FIG. 9) with respect to the condition of graph A of FIG. 7 (or the condition of graph D of FIG. 9) is improved by about 66 mV (about 21%). That is, the display device according to an embodiment of the present invention has superior signal integrity characteristics in the connection portion between the first printed circuit board 400 and the first connector 500 and the connection portion between the second printed circuit board 600 and the second connector 700.

Hereinafter, other embodiments of the present invention will be described. In other embodiments of the present invention, the structure of the first printed circuit boards 401 and 402 is substantially the same as the structure (not illustrated) of the second printed circuit boards, and thus explanation will be made to focus on the structure of the first printed circuit boards 401 and 402.

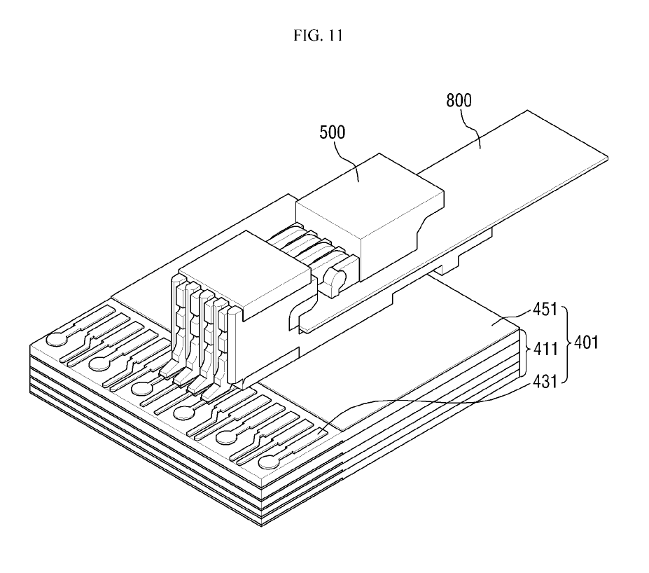

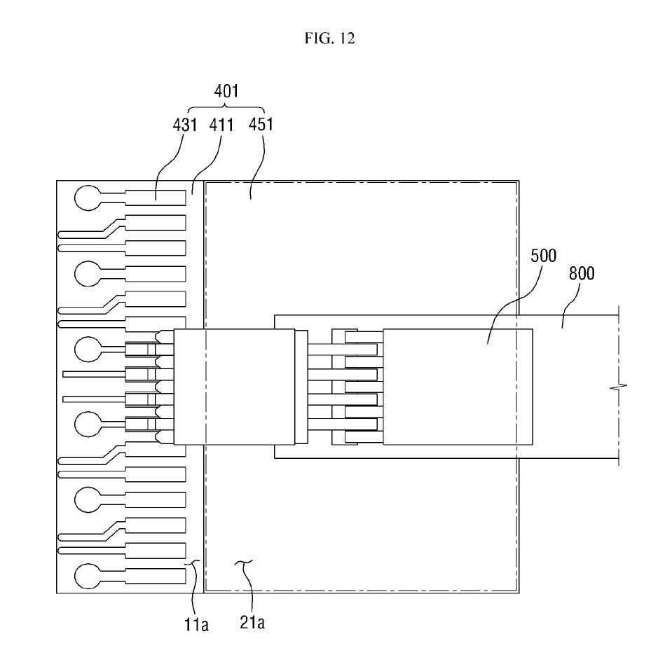

FIG. 11 is a perspective view of a first printed circuit board 401, a first connector 500, and a flexible cable 800 of a display device according to another embodiment of the present invention, and FIG. 12 is a plan view of the first printed circuit board 401, the first connector 500, and the flexible cable 800 of FIG. 11. For convenience in explanation, the same reference numerals are used for substantially the same elements as the elements illustrated in the drawings as described above, and the duplicate explanation thereof will be omitted.

Referring to FIGS. 11 and 12, in a first base member 411 of the first printed circuit board 401, the ranges of a first region 11a and a second region 21a may differ from each other. That is, the first region 11a may mean a center region of the first base member 411, and the second region 21a may mean the whole edge region of the first base member 411. That is, the second region 21a may mean not only the region that corresponds to the first connector 500 but also the whole edge region of the first base member 411. On the other hand, a plurality of first conductive features 431 may be positioned on the first region 11a as described above or may be positioned on the second region 21a as described above. Here, since the range of the second region 21a differs, an area occupied by a first adhesive layer 451 may also differ.

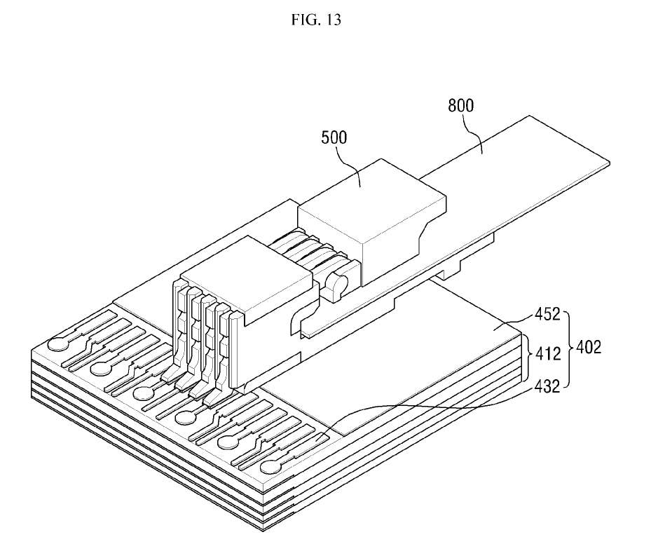

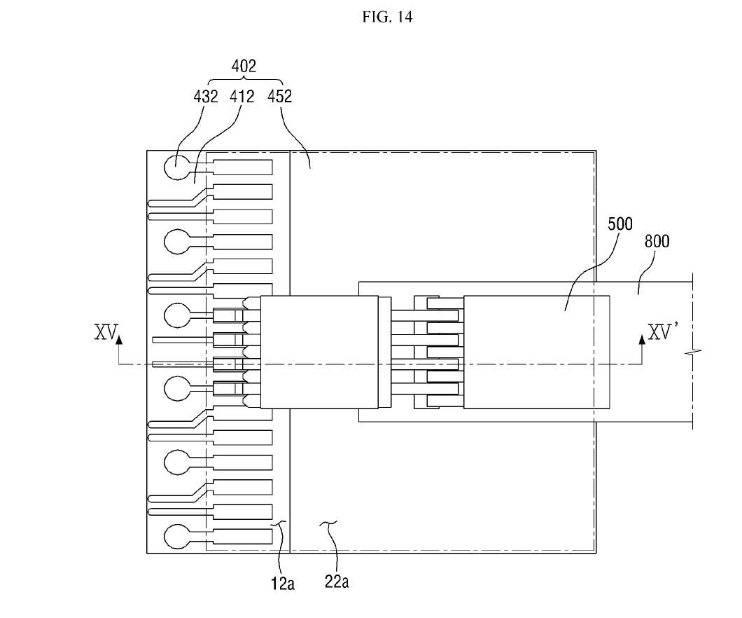

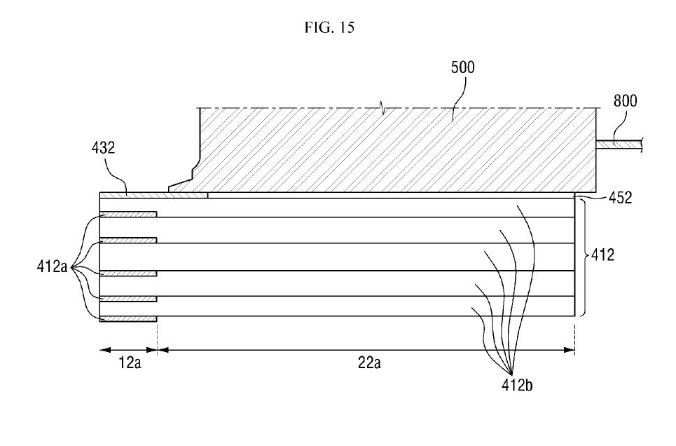

FIG. 13 is a perspective view of a first printed circuit board 402, a first connector 500, and a flexible cable 800 of a display device according to still another embodiment of the present invention. FIG. 14 is a plan view of the first printed circuit board 402, the first connector 500, and the flexible cable 800 of FIG. 13, and FIG. 15 is a cross-sectional view taken along line XV-XV′ of FIG. 14. For convenience in explanation, the same reference numerals are used for substantially the same elements as the elements illustrated in the drawings as described above, and the duplicate explanation thereof will be omitted.

Referring to FIGS. 13 to 15, in a first base member 412 of the first printed circuit board 402, the ranges of a first region 12a and a second region 22a may differ from each other. That is, the first connector 500 may be arranged only on the second region 22a, but may not be arranged on the first region 12a. Further, one side of a plurality of first conductive features 432 may be positioned on the first region 12a, but the other side of the plurality of first conductive features 432, which faces the one side, may be positioned on the second region 22a. That is, the plurality of first conductive features 432 may be arranged to further project from an end portion of a first conductive layer 412a. In other words, end portions of the plurality of first conductive features 432 may not overlap the first conductive layer 412a, but may overlap a first insulating layer 412b. On the other hand, a first adhesive layer 452 may be positioned on the second region 22a as described above.

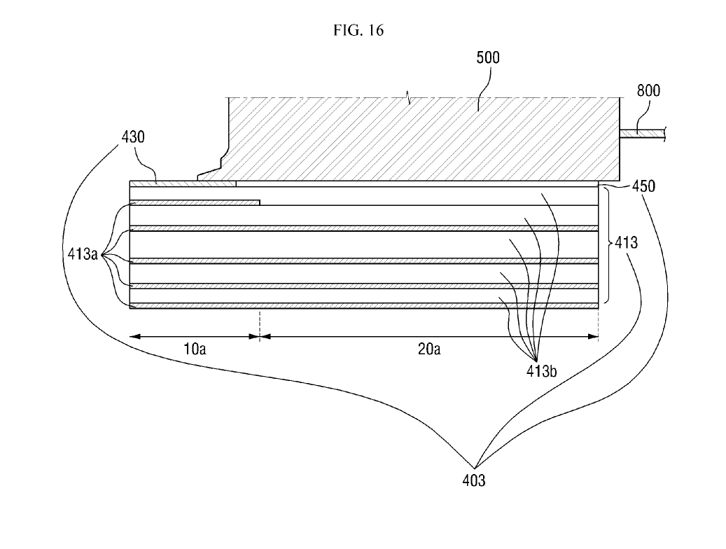

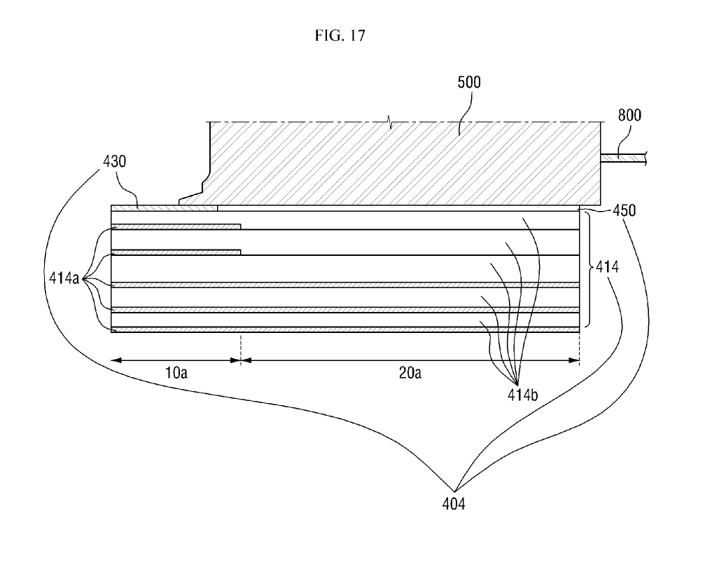

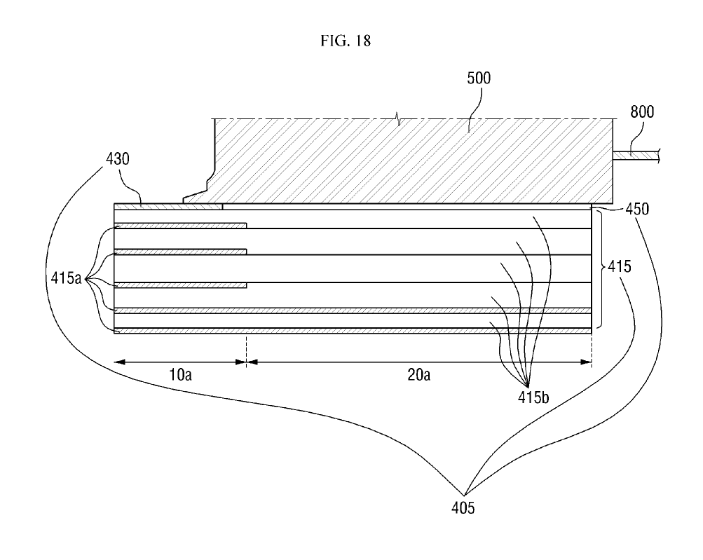

FIGS. 16 to 19 are cross-sectional views of first printed circuit boards 403, 404, 405, and 406 of display devices according to other embodiments of the present invention. For convenience in explanation, the same reference numerals are used for substantially the same elements as the elements illustrated in the drawings as described above, and the duplicate explanation thereof will be omitted.

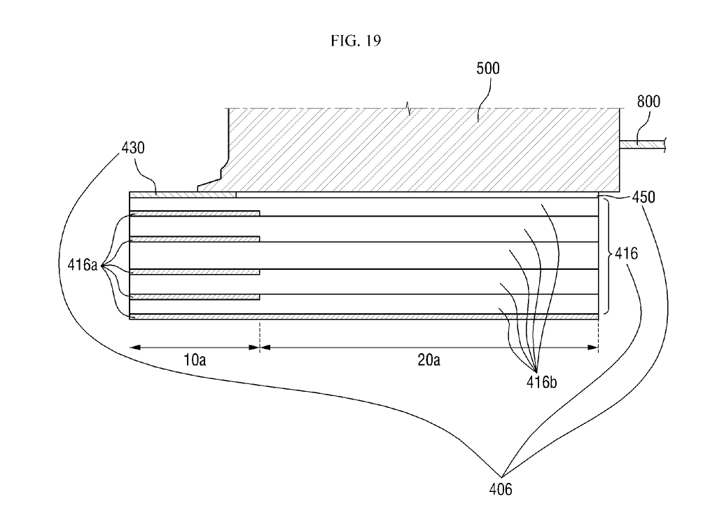

Referring to FIGS. 16 to 19, a plurality of first conductive layers 413a, 414a, 415a, and 416a may all exist on a first region 10a. However, at least one of the plurality of first conductive layers 413a, 414a, 415a, and 416a may not exist on a second region 20a. In an exemplary embodiment, at least one of the plurality of first conductive layers 413a, 414a, 415a, and 416a, which does not exist on the second region 20a, may be adjacent to a first connector 500. That is, it is most helpful in improving the signal integrity characteristics to remove all the first conductive layers 413a, 414a, 415a, and 416a from the second region 20a on which the first connector 500 is arranged. However, even if only one of the plurality of first conductive layers 413a, 414a, 415a, and 416a that are adjacent to the first connector 500 is removed, the parasitic capacitance between the first connector 500 and the plurality of first conductive layers 413a, 414a, 415a, and 416a can be decreased to improve the signal integrity characteristics. Here, as going from a structure (see FIG. 16) in which the first conductive layer 413a that is most adjacent to the first connector 500 is removed from the second region 20a to a structure (see FIG. 19) in which only the first conductive layer 416a that is farthest apart from the first connector 500 remains, the parasitic capacitance between the first connector 500 and the plurality of first conductive layers 413a, 414a, 415a, and 416a can be decreased to improve the signal integrity characteristics.

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A printed circuit board comprising:
a base member including a major surface;
a first region and a second region adjacent to the first region when viewed in a direction perpendicular to the major surface; and
a first conductive pattern layer formed over the major surface and comprising a plurality of conductive features positioned in the first region;
wherein a connector is placed over the major surface and comprises a portion located in the second region, and
wherein the first conductive pattern layer does not comprise a portion formed in the second region such that the first conductive pattern layer does not overlap the connector in the second region when viewed in the direction.

2. The printed circuit board of claim 1, further comprising a second conductive pattern layer embedded in the base member or formed over another surface of the base member, wherein the second conductive pattern layer does not comprise a portion formed in the second region.

3. The printed circuit board of claim 1, wherein the second region comprises at least a part of an edge of the base member.

4. The printed circuit board of claim 2, wherein the connector does not overlap the second conductive pattern layer when viewed in the direction.

5. The printed circuit board of claim 1, wherein two or more of the plurality of conductive features are connected to the connector, and
a minimum width of each of the two or more of the plurality of conductive features that are connected to the connector is smaller than a minimum width of each of the other conductive features that are not connected to the connector.

6. The printed circuit board of claim 5, wherein the minimum width of each of the plurality of conductive features that are connected to the connector is about 0.1 mm.

7. The printed circuit board of claim 1, wherein the base member comprises an insulator that is interposed between the first and second conductive pattern layers.

8. The printed circuit board of claim 2, further comprising a third conductive pattern layer embedded in the base member or formed over the other surface of the base member, wherein the second conductive pattern layer is located between the first and third conductive pattern layers, wherein the base member further comprises at least one insulator between the second and third conductive pattern layer, and
wherein the third conductive pattern layer does not comprise a portion formed in the second region.

9. The printed circuit board of claim 1, further comprising at least one additional conductive pattern layer embedded in the base member or formed over the other surface of the base member, wherein the at least one additional conductive pattern layer does not overlap the connector when viewed in the direction.

10. A printed circuit board comprising:
a base member including a major surface;
a first region and a second region that is adjacent to the first region when viewed in a direction perpendicular to a major surface of the base member;
a plurality of conductive features formed over the major surface and positioned in the first region; and
a plurality of conductive pattern layers, each of which is embedded in the base member or formed over another surface of the base member;
wherein a connector is placed over the major surface and comprises a portion located in the second region,
wherein each of the plurality of conductive pattern layers comprises a portion in the first region, and
wherein at least one of the plurality of conductive pattern layers does not comprise a portion formed in the second region.

11. The printed circuit board of claim 10, wherein the connector comprises at least one conductive terminal connected to at least one of the plurality of conductive features, and extending to the second region.

12. The printed circuit board of claim 11, wherein each of the plurality of conductive pattern layers does not overlap the connector when viewed in the direction.

13. The printed circuit board of claim 10, wherein the base member comprises a plurality of insulator layers that are stacked, and
the plurality of conductive pattern layers and the plurality of insulator layers are alternately stacked with each other.

14. A display device comprising:
a display panel configured to display an image; and
a first printed circuit board connected to the display panel, comprising:
a base member including a major surface,
a first region and a second region adjacent to the first region when viewed in a direction perpendicular to the major surface, and
a conductive pattern layer formed over the major surface and comprising a plurality of conductive features positioned in the first region;
wherein a connector placed over the major surface and comprising a portion located over the second region, and
wherein the first conductive pattern layer does not comprise a portion formed in the second region such that the first conductive pattern layer does not overlap the connector in the second region when viewed in the direction.

15. The display device of claim 14, further comprising a flexible cable comprising an end portion which is connected the connector and does not overlap the first conductive pattern layer when viewed in the direction.

16. The display device of claim 15, further comprising at least one additional conductive pattern layer embedded in the base member or formed over the other surface of the base member, wherein the at least one additional conductive pattern layer does not comprise a portion formed in the second region.

17. The display device of claim 15, further comprising a second printed circuit board connected to the first printed circuit board using the flexible cable.

18. The display device of claim 15, further comprising an additional conductive pattern layer embedded in the base member or formed over the other surface of the base member, wherein the additional conductive pattern layer does not overlap either the connector or the flexible cable when viewed in the direction.

19. The display device of claim 14, wherein two or more of the plurality of second conductive features are connected to the connector, and
a minimum width of each of the two or more of the plurality of second conductive features that are connected to the second connector is smaller than a minimum width of each of the other conductive features that are not connected to the connector.

20. The display device of claim 15, further comprising two or more additional conductive pattern layers embedded in the base member or formed over the other surface of the base member, wherein a first one of the two or more additional conductive pattern layer does not comprise a portion overlapping the end portion of the flexible cable when viewed in the direction, wherein a second one of the two or more additional conductive pattern layers overlaps the end portion of the flexible cable when viewed in the direction.
